(19) United States
(12) Patent Application Publication
(10) Pub. No.: US 2026/0371833 A1
(43) Pub. Date: Nov. 19, 2026

(54) LIGHT-EMITTING ELEMENT, DISPLAY DEVICE, METHOD FOR MANUFACTURING LIGHT-EMITTING ELEMENT, AND METHOD FOR FORMING LIGHT-EMITTING LAYER

(71) Applicant: Sharp Display Technology Corporation, Kameyama City, Mie (JP)

(72) Inventor: Yukio TAKENAKA, Sakai 'City, Osaka (JP)

(21) Appl. No.: 19/475,858

(22) PCT Filed: Apr. 18, 2023
(86) PCT No.: PCT/JP2023/015421

§ 371 Date: Oct. 16, 2025

(51) Int. Cl. H10K 50/115; H10K 71/15

(52) U.S. Cl. CPC H10K 50/115; H10K 71/15

(57) ABSTRACT

A red light-emitting element includes an anode, a cathode, and a red light-emitting layer provided between the anode and the cathode, the red light-emitting layer includes a continuous film including a metal sulfide as a matrix, and a plurality of quantum dots enclosed in the continuous film, and in a cross section of a portion of the red light-emitting layer including cross sections of a predetermined number of quantum dots among the plurality of quantum dots, an area C of the cross section of the portion of the red light-emitting layer is smaller than twice an area B obtained by adding areas of the cross sections of the predetermined number of quantum dots.

### TECHNICAL FIELD

The disclosure relates to a light-emitting element, a display device, a method for manufacturing a light-emitting element, and a method for forming a light-emitting layer.

### BACKGROUND ART

In recent years, quantum dot light-emitting diodes (QLEDs), which are light-emitting elements each including quantum dots, and display devices provided with QLEDs are attracting a lot of attention from a viewpoint that low power consumption, thinning, higher picture quality, and the like can be achieved.

In the field of QLEDs, studies on a light-emitting layer provided in the QLED and a method for forming the light-emitting layer have been actively conducted.

For example, PTL 1 discloses a quantum dot in which a fluoride-containing ligand or a fluoride anion is bonded to a surface thereof.

### CITATION LIST

### Patent Literature

PTL 1: JP 2020-180278 A (published on November 5, 2020)

### SUMMARY

### Technical Problem

The disclosure described in PTL 1 is problematic in that durability and luminous efficiency of the light-emitting element are low.

An object of an aspect of the disclosure is to provide a light-emitting element, a display device, a method for manufacturing a light-emitting element, and a method for forming a light-emitting layer, which can improve durability and luminous efficiency.

### Solution to Problem

In order to solve the above problems, a light-emitting element of the disclosure includes:
an anode;
a cathode; and
a light-emitting layer provided between the anode and the cathode,
in which the light-emitting layer includes a matrix including a metal sulfide and a plurality of quantum dots enclosed in the matrix, and

in a cross section of a portion of the light-emitting layer including cross sections of a predetermined number of quantum dots among the plurality of quantum dots, an area C of the cross section of the portion of the light-emitting layer is smaller than twice an area B obtained by adding areas of the cross sections of the predetermined number of quantum dots.

In order to solve the problems described above, a display device of the disclosure includes the light-emitting element described above.

In order to solve the above problems, a method for manufacturing a light-emitting element of the disclosure includes:
forming the light-emitting layer,
in which the forming the light-emitting layer includes:
preparing a quantum dot solution including the plurality of quantum dots, a precursor of the metal sulfide, and a solvent;
applying the quantum dot solution; and
performing heat treatment of thermally decomposing the precursor of the metal sulfide to form a matrix including the metal sulfide, and
in the preparing the quantum dot solution, an amount of the plurality of quantum dots and an amount of the precursor of the metal sulfide included in the quantum dot solution are adjusted such that a value of ((weight of light-emitting layer−weight of quantum dots)/weight of light-emitting layer)×100% in the light-emitting layer after the heat treatment is greater than 3.3% and less than 35%.

In order to solve the above problems, a method for forming a light-emitting layer of the disclosure includes:
preparing a quantum dot solution including a plurality of quantum dots, a precursor of a metal sulfide, and a solvent;
applying the quantum dot solution; and
performing a heat treatment of thermally decomposing the precursor of the metal sulfide to form a matrix including the metal sulfide,
in which in the preparing the quantum dot solution, an amount of the plurality of quantum dots and an amount of the precursor of the metal sulfide included in the quantum dot solution are adjusted such that a value of ((weight of light-emitting layer−weight of quantum dots)/weight of light-emitting layer)×100% in the light-emitting layer after the heat treatment is greater than 3.3% and less than 35%.

In order to solve the above problems, a method for manufacturing a light-emitting element of the disclosure includes:
forming one of an anode and a cathode;
forming a light-emitting layer by the method for forming a light-emitting layer; and
forming the other of the anode and the cathode.

### Advantageous Effects of Disclosure

According to an aspect of the disclosure, it is possible to provide a light-emitting element, a display device, a method for manufacturing a light-emitting element, and a method for forming a light-emitting layer, which can improve durability and luminous efficiency.

### BRIEF DESCRIPTION OF DRAWINGS

FIG. 1 is a plan view illustrating a schematic configuration of a display device of the present embodiment.

FIG. 2 is a cross-sectional view illustrating a schematic configuration of a display region of the display device of the present embodiment.

FIG. 3 is a cross-sectional view illustrating a schematic configuration of a red light-emitting element provided in the display device of the present embodiment.

FIG. 4 is a cross-sectional view illustrating a schematic configuration of a red light-emitting layer of the red light-emitting element provided in the display device of the present embodiment.

FIG. 5 is a diagram illustrating a case in which the red light-emitting layer of the red light-emitting element provided in the display device of the present embodiment is configured such that a material of a shell of a quantum dot is the same material as that of a continuous film containing a metal sulfide included in the red light-emitting layer.

FIG. 6 is a diagram illustrating a case in which another red light-emitting layer that can be included in the red light-emitting element provided in the display device of the present embodiment is configured such that a material of a shell of a quantum dot is different from a material of the continuous film containing a metal sulfide included in the red light-emitting layer.

FIG. 7 is a table showing an example of a plurality of types of quantum dot solutions containing a plurality of quantum dots, a precursor of a metal sulfide, and a solvent, which can be used in a process of forming a red light-emitting layer of a red light-emitting element provided in the display device of the present embodiment.

FIG. 8 is a diagram schematically illustrating band levels of a hole transport layer, a red light-emitting layer, and an electron transport layer, which are included in the red light-emitting element of the display device of the present embodiment.

FIG. 9 is a diagram for explaining the reason why a good external quantum efficiency (EQE) can be achieved in the red light-emitting element of the display device of the present embodiment.

FIG. 10 is a diagram schematically illustrating band levels of a hole transport layer, a red light-emitting layer, and an electron transport layer, which are included in a red light-emitting element of a comparative example.

FIG. 11 is a diagram for explaining the reason why a good external quantum efficiency (EQE) cannot be achieved in the red light-emitting element of the comparative example.

FIG. 12 is a graph illustrating the relationship between voltage and current density of an electron only device (EOD) including a red light-emitting layer formed using a quantum dot solution having a concentration of 0.02 M and an electron only device (EOD) including a red light-emitting layer formed using a quantum dot solution having a concentration of 0.08 M among the plurality of types of quantum dot solutions shown in FIG. 7.

FIG. 13 is a graph illustrating the relationship between voltage and current density of a hole only device (HOD) including a red light-emitting layer formed using a quantum dot solution having a concentration of 0.02 M and a hole only device (HOD) including a red light-emitting layer formed using a quantum dot solution having a concentration of 0.08 M among the plurality of types of quantum dot solutions shown in FIG. 7.

FIG. 14 is a graph illustrating a degree of brightness decrease due to charge-up of the quantum dots when a red light-emitting element including a red light-emitting layer formed using a quantum dot solution having a concentration of 0.01 M among the plurality of types of quantum dot solutions shown in FIG. 7 and a red light-emitting element of a comparative example illustrated in FIG. 10 are intermittently driven.

FIG. 15 is a graph illustrating photoluminescence (PL) intensities at wavelengths of a red light-emitting layer formed using a quantum dot solution having a concentration of 0.01 M among the plurality of types of quantum dot solutions shown in FIG. 7 and a red light-emitting layer formed using a quantum dot solution having a concentration of 0.16 M of a comparative example.

FIG. 16 is a graph illustrating the relationship between a weight ratio of a continuous film as a media containing a metal sulfide in a plurality of types of red light-emitting layers, which are thin films formed using a plurality of types of quantum dot solutions shown in FIG. 7, and an internal quantum yield (photoluminescence quantum yield (PLQY)).

FIG. 17 is a table showing light-emission peak wavelengths, the internal quantum yields (PLQY), maximum external quantum efficiencies (maximum EQE), and brightness decrease rates after a 5-hour drive of a plurality of types of red light-emitting elements including the red light-emitting layers formed using the plurality of types of quantum dot solutions shown in FIG. 7.

FIG. 18 is a graph illustrating a change in brightness and a change in voltage according to a drive time of a red light-emitting element including a red light-emitting layer formed using a quantum dot solution having a concentration of 0.04 M among the plurality of types of quantum dot solutions shown in FIG. 7.

FIG. 19 is a graph illustrating a change in brightness and a change in voltage according to a drive time of a red light-emitting element including a red light-emitting layer formed using a quantum dot solution having a concentration of 0.08 M among the plurality of types of quantum dot solutions shown in FIG. 7.

FIG. 20 is a flow chart for explaining a process of forming a red light-emitting layer included in a method for manufacturing a red light-emitting element provided in a display device of the present embodiment.

### DESCRIPTION OF EMBODIMENTS

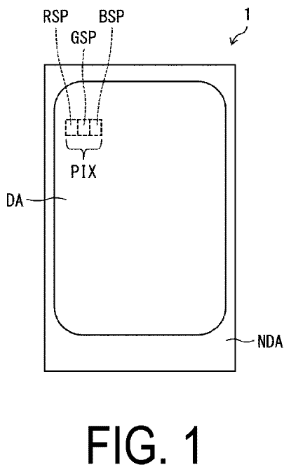

Embodiments of the disclosure will be described with reference to FIG. 1 to FIG. 20 as follows. Hereinafter, for convenience of description, configurations having the same functions as those described in a specific embodiment are denoted by the same reference signs, and descriptions thereof will be omitted.

FIG. 1 is a plan view illustrating a schematic configuration of a display device 1 of the present embodiment.

As illustrated in FIG. 1, the display device 1 includes a frame region NDA and a display region DA. A plurality of pixels PIX are provided in the display region DA of the display device 1, and each pixel PIX includes a red subpixel RSP, a green subpixel GSP, and a blue subpixel BSP. In the present embodiment, although an example in which one pixel PIX includes the red subpixel RSP, the green subpixel GSP, and the blue subpixel BSP is described, the disclosure is not limited thereto. For example, one pixel PIX may further include a subpixel of another color in addition to the red subpixel RSP, the green subpixel GSP, and the blue subpixel BSP.

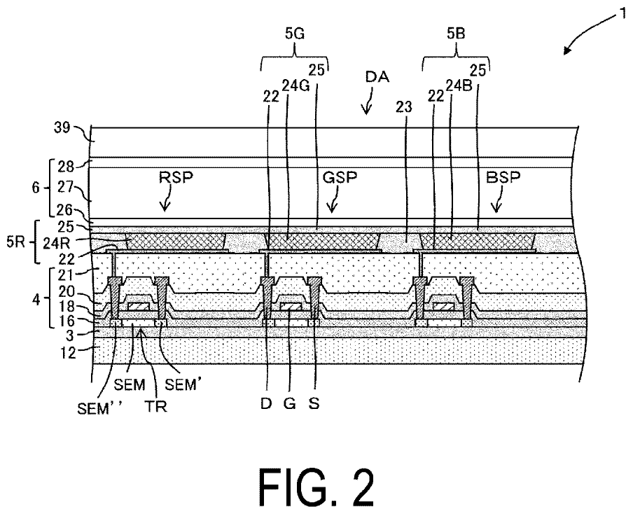

FIG. 2 is a cross-sectional view illustrating a schematic configuration of the display region DA of the display device 1 of the present embodiment.

As illustrated in FIG. 2, in the display region DA of the display device 1, a barrier layer 3, a thin film transistor layer 4 including transistors TR, a red light-emitting element 5R, a green light-emitting element 5G, a blue light-emitting element 5B, a bank 23, a sealing layer 6, and a function film 39 are provided on a substrate 12 in this order from the substrate 12 side.

The red subpixel RSP provided in the display region DA of the display device 1 includes the red light-emitting element 5R, the green subpixel GSP provided in the display region DA of the display device 1 includes the green light-emitting element 5G, and the blue subpixel BSP provided in the display region DA of the display device 1 includes the blue light-emitting element 5B.

The substrate 12 may be, for example, a resin substrate made of a resin material such as a polyimide, or may be a glass substrate. In the present embodiment, the display device 1 is a flexible display device, and thus, a case will be described as an example in which a resin substrate made of the resin material such as a polyimide is used as the substrate 12; however, the disclosure is not limited thereto. In a case in which the display device 1 is a non-flexible display device, the glass substrate may be used as the substrate 12.

The barrier layer 3 is a layer that inhibits foreign matter, such as water and oxygen, from entering a transistor TR, the red light-emitting element 5R, the green light-emitting element 5G, and the blue light-emitting element 5B, and can be formed of, for example, a silicon oxide film, a silicon nitride film, or a silicon oxynitride film, or a layered film thereof formed by using a chemical vapor deposition (CVD) method.

A transistor TR portion of the thin film transistor layer 4 including the transistor TR includes a semiconductor film SEM, doped semiconductor films SEM′ and SEM″, an inorganic insulating film 16, a gate electrode G, an inorganic insulating film 18, an inorganic insulating film 20, a source electrode S, a drain electrode D, and a flattening film 21, and a portion other than the transistor TR portion of the thin film transistor layer 4 including the transistor TR includes the inorganic insulating film 16, the inorganic insulating film 18, the inorganic insulating film 20, and the flattening film 21.

The semiconductor films SEM, SEM′ and SEM″ may be formed of low-temperature polysilicon (LTPS) or an oxide semiconductor (for example, an In—Ga—Zn—O based semiconductor), for example. Although a case in which the transistor TR has a top gate structure is exemplified in the present embodiment, the disclosure is not limited thereto, and the transistor TR may have a bottom gate structure.

The gate electrode G, the source electrode S, and the drain electrode D may be formed of a single-layer film or a layered film of a metal including, for example, at least one of aluminum, tungsten, molybdenum, tantalum, chromium, titanium, or copper.

The inorganic insulating film 16, the inorganic insulating film 18, and the inorganic insulating film 20 can be formed of, for example, a silicon oxide film, a silicon nitride film, or a silicon oxynitride film, or a layered film thereof, formed by using the CVD method.

The flattening film 21 can be formed of organic materials capable of coating such as a polyimide and acrylic, but may be formed of an inorganic film.

The red light-emitting element 5R included in the red subpixel RSP includes an anode 22 provided above the flattening film 21, a function layer 24R including the red light-emitting layer, and a cathode 25; the green light-emitting element 5G included in the green subpixel GSP includes the anode 22 provided above the flattening film 21, a function layer 24G including a green light-emitting layer, and the cathode 25; and the blue light-emitting element 5B included in the blue subpixel BSP includes the anode 22 provided above the flattening film 21, a function layer 24B including a blue light-emitting layer, and the cathode 25. Note that the bank 23 with insulating properties covering an edge of the anode 22 is formed, for example, by applying an organic material, such as polyimide or acrylic, and then patterning the organic material by photolithography but may be formed of an inorganic film.

Although a case in which the red light-emitting element 5R, the green light-emitting element 5G, and the blue light-emitting element 5B are in an orderly-layered structure is exemplified in the present embodiment, the disclosure is not limited to this example, and the red light-emitting element 5R, the green light-emitting element 5G, and the blue light-emitting element 5B may be in an inversely-layered structure. The red light-emitting element 5R in the orderly-layered structure includes the anode 22 and the cathode 25 provided as an upper layer above the anode 22, and the function layer 24R including the red light-emitting layer provided between the anode 22 and the cathode 25 can be formed by layering, for example, a hole injection layer, a hole transport layer, a red light-emitting layer, an electron transport layer, and an electron injection layer in this order from an anode 22 side. Of the hole injection layer, the hole transport layer, the electron transport layer, and the electron injection layer in the function layer 24R including the red light-emitting layer, other than the red light-emitting layer, one or more layers may be omitted as appropriate. In the present embodiment, although a case in which the function layer 24R including a red light-emitting layer 24REM is formed by layering a hole transport layer 24HT, the red light-emitting layer 24REM, and an electron transport layer 24ET in this order from the anode 22 side, is described as an example, the disclosure is not limited thereto.

Although not illustrated, the red light-emitting element in the inversely-layered structure includes the cathode and the anode provided as an upper layer above the cathode, and the function layer including the red light-emitting layer 24REM provided between the cathode and the anode can be formed by layering, for example, an electron injection layer, an electron transport layer, the red light-emitting layer 24REM, a hole transport layer, and a hole injection layer in this order from the cathode side. Of the electron injection layer, the electron transport layer, the hole transport layer, and the hole injection layer in the function layer including the red light-emitting layer 24REM, other than the red light-emitting layer 24REM, one or more layers may be omitted as appropriate. Although the red light-emitting element and the like have been described above, a green light-emitting element and the like or a blue light-emitting element and the like can be described in exactly the same manner, and can be understood as such. That is, the description can be made in exactly the same manner by replacing the “red” portion of the description here with “green” or “blue” and replacing the “R” portion of the reference numeral with “G” or “B”, and it can be understood as such.

A material used for the hole injection layer is not particularly limited as long as the material is a hole injection material that can stabilize the injection of holes into the light-emitting layer, and for example, a composite (PEDOT: PSS) of poly(3,4-ethylenedioxythiophene) (PEDOT) and polystyrene sulfonic acid (PSS) can be used.

As a material used for the hole transport layer, for example, an organic material such as poly[(9,9-dioctylfluorenyl-2,7-diyl)-co-(4,4′-(N-(4-sec-butylphenyl))diphenylamine)] (TFB), N,N′-bis(4-butylphenyl)-N,N′-bis(phenyl)-benzidine (poly-TPD), polyvinyl carbazole (PVK), or the like may be used, and nanoparticles having hole transport properties such as NiO particles may be used. In the present embodiment, a case in which N,N′-bis(4-butylphenyl)-N,N′-bis(phenyl)-benzidine (poly-TPD) is used as the hole transport layer 24HT will be described as an example, but the disclosure is not limited thereto.

As a material used for the electron transport layer, for example, an organic material such as 2,2′,2″-(1,3,5-benzinetriyl)-tris(1-phenyl-1-H-benzimidazole) (TPBi) may be used, and nanoparticles having electron transport properties such as ZnO particles may be used. In the present embodiment, a case in which particles of oxides containing Zn and Mg, for example, Zn_{0.9}Mg_{0.1}O particles are used as the electron transport layer 24ET will be described as an example, but the disclosure is not limited thereto.

A material used for the electron injection layer is not particularly limited as long as the material is an electron injection material that can stabilize the injection of electrons into the light-emitting layer, and for example, alkali metals or alkaline earth metals, oxides of alkali metals or alkaline earth metals, fluorides of alkali metals or alkaline earth metals, and organic complexes of alkali metals, such as aluminum, strontium, calcium, lithium, cesium, magnesium oxide, aluminum oxide, strontium oxide, lithium oxide, lithium fluoride, magnesium fluoride, strontium fluoride, calcium fluoride, barium fluoride, cesium fluoride, and polymethyl methacrylate sodium polystyrene sulfonate can be used.

In addition, although a case in which the function layer 24R including the red light-emitting layer, the function layer 24G including the green light-emitting layer, and the function layer 24B including the blue light-emitting layer each include the hole transport layer formed using the same material in the same process, and the electron transport layer formed using the same material in the same process is exemplified in the present embodiment, the disclosure is not limited thereto. For example, the hole injection layers included respectively in the function layers 24R, 24G, and 24B may be formed using the same material in the same process or may be formed of materials different from each other, and the hole injection layers respectively included in two function layers of the function layers 24R, 24G, and 24B may be formed using the same material in the same process, and only the hole injection layer included in the remaining one function layer may be formed using a different material in another process. In addition, for example, the hole transport layers included respectively in the function layers 24R, 24G, and 24B may be formed of materials different from each other, and the hole transport layers included respectively in two function layers of the function layers 24R, 24G, and 24B may be formed of the same material in the same process, and only the hole transport layer included in the remaining one function layer may be formed of a different material in another process. Further, also as for the electron transport layer, the same materials and the same processes can be selected in a desired combination for the function layers 24R, 24G, and 24B, as appropriate, as in the hole transport layer.

Although a case in which the red light-emitting element 5R, the green light-emitting element 5G, and the blue light-emitting element 5B are all quantum dot light-emitting diodes (QLEDs) is exemplified in the present embodiment, the disclosure is not limited thereto, and at least one or more of the red light-emitting element 5R, the green light-emitting element 5G, and the blue light-emitting element 5B may be a QLED, and the remaining may be an OLED.

As in the present embodiment, when all of the red light-emitting element 5R, the green light-emitting element 5G, and the blue light-emitting element 5B are QLEDs, the light-emitting layers included in the respective color light-emitting elements include quantum dots. The quantum dots may have, for example, a core structure, a core/shell structure, a core/shell/shell structure, or a shell structure with a continuously varying ratio. Note that the shell may partially cover the core, but it is better to completely cover the core. A core material of the quantum dots can be formed of, for example, crystals of II-VI semiconductors such as MgS, MgSe, MgTe, CaS, CaSe, CaTe, BaS, BaSe, BaTe, ZnS, ZnSe, ZnTe, CdS, CdSe, CdTe, PbS, PbSe, HgS, HgSe, and HgTe, crystals of III-V semiconductors such as GaAs, GaP, InN, InAs, InP, and InSb, crystals of III-VI semiconductors such as Ga₃S₂, Ga₂Se₃, In₂S₃, and In₂Se₃, crystals of I-III-VI semiconductors such as CuInGaS, AgInGaS, CuInGaS, AgInGaZnS, CuInGaSe, and AgInGaSe, crystals of IV semiconductors such as C and Si, crystals of semiconductors having a perovskite structure such as CsPbI₃, CsPbBr₃, and CsPbCl₃, and the like. A shell material is selected from the same group of materials as the core material, and preferably has a lattice constant close to that of the core material and a band gap larger than that of the core material.

When the quantum dots described above include an organic ligand or an inorganic ligand (for example, a halogen ligand) disposed on a surface of the quantum dot or in the vicinity of the surface of the quantum dot, it means that the quantum dot may include the organic ligand or the inorganic ligand. Thus, when the quantum dots include a ligand such as an organic ligand or an inorganic ligand, each of the red light-emitting layer 24REM, the green light-emitting layer, and the blue light-emitting layer may also include a ligand.

Note that in the quantum dots, the maximum width excluding a ligand portion is equal to or less than 100 nm. In the quantum dots, a shape excluding the ligand portion is not particularly restricted as long as the shape is within a range satisfying the maximum width, and the shape is not limited to a spherical three-dimensional shape (circular cross-sectional shape). The shape of the quantum dot may be, for example, a polygonal cross-sectional shape, a rod-shaped three-dimensional shape, a branch-shaped three-dimensional shape, or a three-dimensional shape having unevenness on the surface thereof, or a combination of them.

The red light-emitting element 5R, the green light-emitting element 5G, and the blue light-emitting element 5B illustrated in FIG. 2 may be a top-emitting type or a bottom-emitting type. Since the red light-emitting element 5R, the green light-emitting element 5G, and the blue light-emitting element 5B have the orderly-layered structures in which the cathode 25 is disposed as an upper layer above the anode 22, in order to form the top-emitting type, the anode 22 may be formed of an electrode material that reflects visible light and the cathode 25 may be formed of an electrode material that allows visible light to pass through, and in order to form the bottom-emitting type, the anode 22 may be formed of an electrode material that allows visible light to pass through and the cathode 25 may be formed of an electrode material that reflects visible light. On the other hand, when the red light-emitting element, the green light-emitting element, and the blue light-emitting element have the inversely-layered structures in which the anode 22 is disposed as an upper layer above the cathode 25, in order to form the top-emitting type, the cathode 25 may be formed of an electrode material that reflects visible light and the anode 22 may be formed of an electrode material that allows visible light to pass through, and in order to form the bottom-emitting type, the cathode 25 may be formed of an electrode material that allows visible light to pass through and the anode 22 may be formed of an electrode material that reflects visible light.

The electrode material that reflects visible light is not particularly limited as long as the material can reflect visible light and has electrical conductivity, and examples thereof include metal materials such as Al, Mg, Li, and Ag, alloys of the metal materials, a layered body of the metal materials and transparent metal oxides (for example, indium tin oxide, indium zinc oxide, indium gallium zinc oxide, and the like), or a layered body of the alloys and the transparent metal oxides.

On the other hand, the electrode material that allows visible light to pass through is not particularly limited as long as the material can allow visible light to pass through and has electrical conductivity, and examples thereof include a thin film formed of a transparent metal oxide (for example, indium tin oxide, indium zinc oxide, indium gallium zinc oxide, and the like) or a metal material such as Al and Ag, or a nano wire formed of a metal material such as Al and Ag.

A typical electrode forming method can be used as the method of film-forming the anode 22 and the cathode 25, and examples thereof include Physical Vapor Deposition (PVD) such as vacuum vapor deposition, sputtering, Electron Beam (EB) vapor deposition, and ion plating, or Chemical Vapor Deposition (CVD). Further, the method of patterning the anode 22 and the cathode 25 is not particularly limited as long as the method is capable of precisely forming a desired pattern, and specific examples include a photolithography method and an ink-jet method.

The sealing layer 6 is a transparent film and, for example, may be formed of an inorganic sealing film 26 covering the cathode 25, an organic film 27 serving as an upper layer overlying the inorganic sealing film 26, and an inorganic sealing film 28 serving as an upper layer overlying the organic film 27. The sealing layer 6 inhibits foreign matters such as water and oxygen from intruding into the red light-emitting element 5R, the green light-emitting element 5G, and the blue light-emitting element 5B.

The inorganic sealing film 26 and the inorganic sealing film 28 are both inorganic films and may be composed of, for example, a silicon oxide film, a silicon nitride film, a silicon oxynitride film, or a layered film thereof, formed by using the CVD method. The organic film 27 is a transparent organic film having a flattening effect, and may be composed of an organic material capable of coating such as an acrylic, for example. The organic film 27 may be formed by an ink-jet method, for example. Although the case in which the sealing layer 6 is formed of two layers of an inorganic film and one layer of an organic film provided between the two layers of the inorganic film is exemplified in the present embodiment, the layering order of the two layers of the inorganic film and the one layer of the organic film is not limited thereto. Furthermore, the sealing layer 6 may be composed of only an inorganic film, may be composed of only an organic film, may be composed of one layer of an inorganic film and two layers of an organic film, or may be composed of two or more layers of an inorganic film and two or more layers of an organic film.

The function film 39 is a film with at least one of an optical compensation function, a touch sensor function, and a protection function, for example.

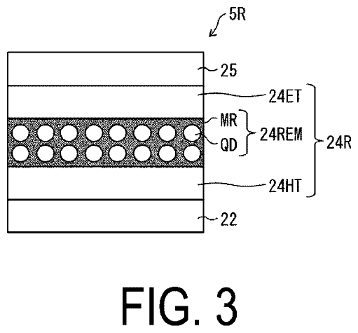

FIG. 3 is a cross-sectional view illustrating a schematic configuration of the red light-emitting element 5R provided in the display device 1 of the present embodiment.

As illustrated in FIG. 3, the red light-emitting element 5R includes the anode 22, the cathode 25, and the red light-emitting layer 24REM provided between the anode 22 and the cathode 25.

In the present embodiment, the function layer 24R including the red light-emitting layer 24REM included in the red light-emitting element 5R is configured by layering the hole transport layer 24HT, the red light-emitting layer 24REM, and the electron transport layer 24ET in this order from the anode 22 side.

As illustrated in FIG. 3, the red light-emitting layer 24REM includes a continuous film MR containing a metal sulfide and a plurality of quantum dots QD enclosed in the continuous film MR. In the present embodiment, a case in which all the quantum dots QD are enclosed in the continuous film MR in the red light-emitting layer 24REM will be described as an example, but the disclosure is not limited thereto as long as the red light-emitting layer 24REM includes a plurality of quantum dots QD enclosed in the continuous film MR. Note that the continuous film MR may be a matrix.

The continuous film MR is a continuous matrix. The matrix means a member that includes and holds other objects, and can be referred to as a base material, a parent material, or a filler. The continuous matrix may be a member that includes and holds a plurality of quantum dots QD. The matrix may be filled in the light-emitting layer. The matrix may fill a region (space) between two quantum dots QD adjacent to each other. The matrix may fill a region (space) other than the plurality of quantum dots QD in the light-emitting layer. The fact that the matrix fills the spaces between the plurality of quantum dots QD means that the matrix fills the region between two quantum dots QD adjacent to each other, and it is sufficient to confirm the fact. Since the desired effect is achieved when the matrix fills the region between at least two quantum dots QD adjacent to each other, it is not necessary to know that the matrix fills the spaces between all (more than two) quantum dots QD in a certain range. An outer edge (upper face and lower face) of the light-emitting layer may be covered with the matrix. Alternatively, a portion of the matrix may be from the outer edges of the light-emitting layer, and a quantum dot group may be positioned away from the outer edges. The outer edges of the light-emitting layer may not be formed only by the matrix, and a part of the quantum dot group may be exposed from the matrix. The matrix may be indicated as a portion of the light-emitting layer excluding the quantum dot group. When the light-emitting layer includes a plurality of quantum dots QD enclosed in a matrix, the matrix may be formed so as to partially or completely fill the space formed between two adjacent quantum dots QD. A gap may be present in the light-emitting layer. When the light-emitting layer includes a plurality of quantum dots QD enclosed in a matrix, the light-emitting layer may include the plurality of quantum dots QD, and the matrix may partially or completely fill a region other than the plurality of quantum dots QD. Each of two adjacent quantum dots QD included in the plurality of quantum dots QD may be embedded in the matrix at intervals.

The continuous matrix, that is, the continuous film MR may be a matrix that is continuous in a range of an area of the light-emitting layer equal to or larger than 1000 nm². The continuous film MR, that is, the continuous matrix means a film not divided by a material other than a material constituting the continuous film MR, that is, the continuous matrix in one plane. That is, the matrix may be connected to each other even in a part, and a case in which the quantum dots or other materials are included therebetween is not excluded. The term “divided” means that a layer is completely separated by another layer without a partially connected portion. The continuous film MR, that is, the continuous matrix may be an integrated film connected without interruption by chemical bonding of the material constituting the matrix. The continuous matrix may be made of the same material as a shell of the quantum dot QD. In this case, an average distance between adjacent cores of adjacent two quantum dots QD (core-to-core distance) may be equal to or greater than 3 nm, or equal to or greater than 5 nm. The core-to-core distance is an average of distances between adjacent 20 cores in a space including the 20 cores. The core-to-core distance may be kept wider than a distance when the shells are in contact with each other. Note that when a cross section of the particle is observed, the size of the cross-sectional area varies depending on the cutting position of the particle. Therefore, a diameter of a circle having the same area as an average cross-sectional area of the particles having the largest cross-sectional area in the top 10% can be regarded as a core diameter.

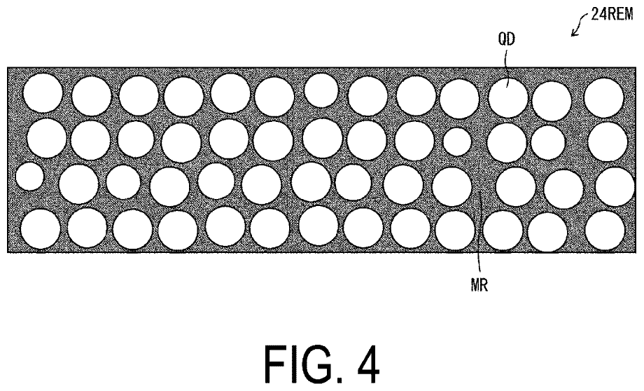

FIG. 4 is a cross-sectional view illustrating a schematic configuration of the red light-emitting layer 24REM of the red light-emitting element 5R provided in the display device 1 of the present embodiment.

As illustrated in FIG. 4, in a cross section of a portion of the red light-emitting layer 24REM including cross sections of a predetermined number of quantum dots QD among the plurality of quantum dots QD included in the red light-emitting layer 24REM, an area C of the cross section of the portion of the red light-emitting layer 24REM is smaller than twice an area B obtained by adding the areas of the cross sections of the predetermined number of quantum dots QD.

In the present embodiment, as illustrated in FIG. 4, in a cross section of a portion of the red light-emitting layer 24REM including cross sections of 52 quantum dots QD, for example, among the plurality of quantum dots QD included in the red light-emitting layer 24REM, when an area A (hatched portion in FIG. 4) of a cross section of the continuous film MR including metal sulfide and an area B obtained by adding the areas of the cross sections of the 52 quantum dots QD are compared, the area A is smaller than the area B. In addition, when an area of the cross section of a portion of the red light-emitting layer 24REM including the cross sections of 52 quantum dots QD is defined as an area C, that is, when an area of the cross section of a portion of the entire light-emitting layer including the cross section of the quantum dots QD and the matrix are defined as the area C, the area C is smaller than twice the area B obtained by adding the areas of the cross sections of the 52 quantum dots QD. Here, although the case of the cross section of a portion of the red light-emitting layer 24REM including 52 quantum dots QD has been described as an example, the disclosure is not limited thereto. The number of the quantum dots may be 50 or more, may be 50, or may be 100. Note that as illustrated in FIG. 4, the sizes of the cross sections of the 52 quantum dots QD vary depending on the cutting positions even if the quantum dots QD have the same particle diameter. In addition, for example, in a case in which a cross section of the red light-emitting layer 24REM is observed with a transmission electron microscopy (TEM), when a gap having an identifiable size is included, a cross-sectional area of the gap is not included in the area A of the cross section of the continuous film MR including the metal sulfide.

In the present embodiment, the red light-emitting layer 24REM is described by taking as an example a case in which the area A of the cross section of the continuous film MR containing a metal sulfide is smaller than the area B obtained by adding the areas of the cross sections of a predetermined number of, for example, 50 or more quantum dots QD in the cross section obtained by cutting any portion of the red light-emitting layer 24REM, but the disclosure is not limited thereto, and the red light-emitting layer 24REM may include a cross section including the cross sections of the predetermined number of, for example, 50 or more quantum dots QD obtained by cutting a certain portion of the red light-emitting layer 24REM, in which the area A of the cross section of the continuous film MR containing a metal sulfide is smaller than the area B obtained by adding the areas of the cross sections of the predetermined number of, for example, 50 or more quantum dots QD. The fact that the red light-emitting layer 24REM partially having a cross section in which “the area A of the cross section of the continuous film MR containing the metal sulfide is smaller than the area B obtained by adding the areas of the cross sections of a predetermined number of, for example, 50 or more quantum dots QD” means that the red light-emitting layer 24REM has a portion in which “the area A of the cross section of the continuous film MR containing the metal sulfide is smaller than the area B obtained by adding the areas of the cross sections of a predetermined number of, for example, 50 or more quantum dots QD”. The inventors of the disclosure have confirmed that when the red light-emitting layer 24REM includes a cross section including cross sections of a predetermined number of, for example, 50 or more quantum dots QD, in which “the area A of the cross section of the continuous film MR including metal sulfide is smaller than the area B obtained by adding the areas of the cross sections of the predetermined number of, for example, 50 or more quantum dots QD”, the balance of carriers and the external quantum efficiency (EQE) can be improved, and the decrease in brightness due to the charge-up of the quantum dots can be suppressed. Therefore, the red light-emitting layer 24REM may include, for example, a cross section including cross sections of a predetermined number of, for example, 50 quantum dots QD, in which “the area A of the cross section of the continuous film MR including the metal sulfide is smaller than the area B obtained by adding the areas of the cross sections of the 50 quantum dots QD”, or may include a cross section including cross sections of 100 quantum dots QD, in which “the area A of the cross section of the continuous film MR including the metal sulfide is smaller than the area B obtained by adding the areas of the cross sections of the 100 quantum dots QD”. Note that the area of the cross section of a portion of the red light-emitting layer 24REM including the cross sections of 52 quantum dots QD may be, for example, an area obtained by observing the cross section of the portion of the red light-emitting layer 24REM including the cross sections of the 52 quantum dots QD illustrated in FIG. 4 with a transmission electron microscopy (TEM) and excluding gaps that can be identified with the transmission electron microscopy (TEM) from a value of a horizontal width of the cross section of a portion of the red light-emitting layer 24REM illustrated in FIG. 4 x a vertical height of the cross section of the portion of the red light-emitting layer 24REM illustrated in FIG. 4.

In a cross section of a portion of the red light-emitting layer 24REM including cross sections of 50 or more quantum dots QD among a plurality of quantum dots QD included in the red light-emitting layer 24REM, the area A of the cross section of the continuous film MR including the metal sulfide, that is, the area A obtained by subtracting the area B from the area C is preferably 3.4% or more and 27.0% or less of the area B obtained by adding the areas of the cross sections of the predetermined number of, for example, the 50 or more quantum dots QD.

A cross section of a portion of the red light-emitting layer 24REM including cross sections of a predetermined number of, for example, 50 or more quantum dots QD illustrated in FIG. 4 may be observed with a transmission electron microscopy (TEM), and in this case, an image of the transmission electron microscopy (TEM) includes a first region having a higher electron density in transmission of an irradiated electron beam and a second region having a lower electron density, and an area of the first region may be defined as an area A of the cross section of the metal-sulfide-containing continuous film MR obtained by subtracting the area B from the area C, and an area of the second region may be defined as an area B obtained by adding the areas of the cross sections of the 52 quantum dots QD.

For example, by setting the display of the image of the transmission electron microscopy (TEM), in a region containing a heavier element, the irradiated electron beam is less likely to pass through, the electron density is low, and the region can be displayed in a lighter color, and in a region containing a lighter element, the irradiated electron beam is likely to pass through, the electron density is high, and the region can be displayed in a darker color.

Since the quantum dot QD contains Se, In, and Cd, which are heavier elements than Zn, such as ZnSe, InP, and CdS, the quantum dot QD is displayed in a lighter color, and the area B, which is the area of the second region having a lower electron density, may be obtained from an area of a region displayed in a lighter color in the image of the transmission electron microscopy (TEM). On the other hand, since the continuous film MR containing a metal sulfide (for example, ZnS) contains Zn, which is a lighter element than Se, the continuous film MR is displayed in a darker color, and the area A, which is the area of the first region having a higher electron density, may be obtained from an area of a region displayed in a darker color in the image of the transmission electron microscopy (TEM).

After the composition of the continuous film MR containing the metal sulfide and the quantum dots QD included in the red light-emitting layer 24REM is determined by the elemental analysis of the red light-emitting layer 24REM, X-ray diffraction may be performed on a cross section of a portion of the red light-emitting layer 24REM including cross sections of a predetermined number of, for example, 50 or more quantum dots QD illustrated in FIG. 4. The cross section of a portion of the red light-emitting layer 24REM including cross sections of 50 or more quantum dots QD may include a first region having a unique diffraction peak of the metal sulfide by X-ray diffraction and a second region having a unique diffraction peak of the quantum dots QD by X-ray diffraction, and the area of the first region in the cross section of the portion of the red light-emitting layer 24REM obtained based on the unique diffraction peak of the metal sulfide by X-ray diffraction may be the area A of the cross section of the continuous film MR containing the metal sulfide, the area A being obtained by subtracting the area B from the area C, and the area of the second region in the cross section of the portion of the red light-emitting layer 24REM obtained based on the unique diffraction peak of the quantum dots QD by X-ray diffraction may be the area B obtained by adding the areas of the cross sections of the 50 or more quantum dots QD.

In the cross section of a portion of the red light-emitting layer 24REM including the cross sections of 50 or more quantum dots QD illustrated in FIG. 4, a number-average inter-quantum dot distance of the 50 or more quantum dots QD is preferably 1 nm or more and 5 nm or less. Note that the number-average inter-quantum dot distance can be obtained by determining N distances (N is a positive integer of 2 or more) between quantum dots QD having the shortest distances between the quantum dots among adjacent quantum dots QD in a cross section of a portion of the red light-emitting layer 24REM including cross sections of 50 or more quantum dots QD illustrated in FIG. 4, and calculating (the sum of the N shortest distances/N).

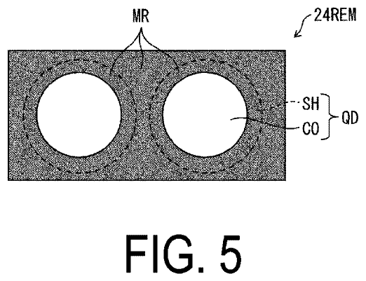

FIG. 5 is a diagram illustrating a case in which the red light-emitting layer 24REM of the red light-emitting element 5R provided in the display device 1 of the present embodiment is configured such that a material of a shell SH of the quantum dot QD is the same material as that of the continuous film MR including the metal sulfide included in the red light-emitting layer 24REM.

As illustrated in FIG. 5, in the present embodiment, a case in which the quantum dots QD included in the red light-emitting layer 24REM include a core CO and the shell SH, the shell SH of the quantum dots QD is formed of a metal sulfide, and both the metal sulfide contained in the continuous film MR and the metal sulfide forming the shell SH of the quantum dots QD are ZnS will be described as an example, but the disclosure is not limited thereto. The metal sulfide contained in the continuous film MR and the metal sulfide forming the shell SH of the quantum dots QD may be different metal sulfides. The metal sulfide may contain one or more metal elements selected from Zn, Mg, and Ga, and may be any one of zinc sulfide (for example, ZnS), magnesium zinc sulfide (for example, ZnMgS), gallium sulfide (for example, GaS), zinc sulfide selenide (for example, ZnSeS), zinc sulfide telluride (for example, ZnTeS), magnesium sulfide (for example, MgS), and gallium zinc sulfide (for example, ZnGaS). The band gap of the continuous film MR containing the metal sulfide serving as a matrix is larger than the band gap of the core CO of the quantum dot QD.

As in the present embodiment illustrated in FIG. 5, when the shell SH of the quantum dot QD is made of a metal sulfide, for example, when both the metal sulfide contained in the continuous film MR and the metal sulfide constituting the shell SH of the quantum dot QD are ZnS, the shell SH of the quantum dot QD made of a metal sulfide is formed continuously with the continuous film MR, and thus can be regarded as the continuous film MR.

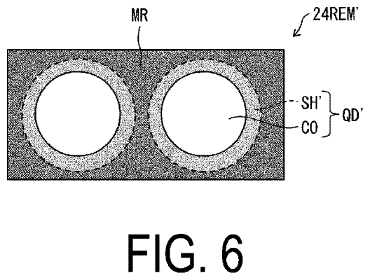

FIG. 6 is a diagram illustrating a case in which another red light-emitting layer 24REM′ that can be included in the red light-emitting element 5R provided in the display device 1 of the present embodiment is configured such that a material of a shell SH′ of a quantum dot QD′ is different from a material of the continuous film MR containing the metal sulfide included in the red light-emitting layer 24REM′.

As illustrated in FIG. 6, the quantum dot QD′ included in the red light-emitting layer 24REM′ includes the core CO and the shell SH′, the shell SH′ of the quantum dot QD′ is formed of a material other than the metal sulfide, and the band gap of the continuous film MR containing the metal sulfide serving as a matrix is larger than the band gap of the core CO of the quantum dot QD′.

As illustrated in FIG. 6, when the shell SH′ of the quantum dot QD′ is formed of a material other than a metal sulfide, the shell SH′ of the quantum dot QD′ does not contain a metal sulfide, and thus is a quantum dot QD.

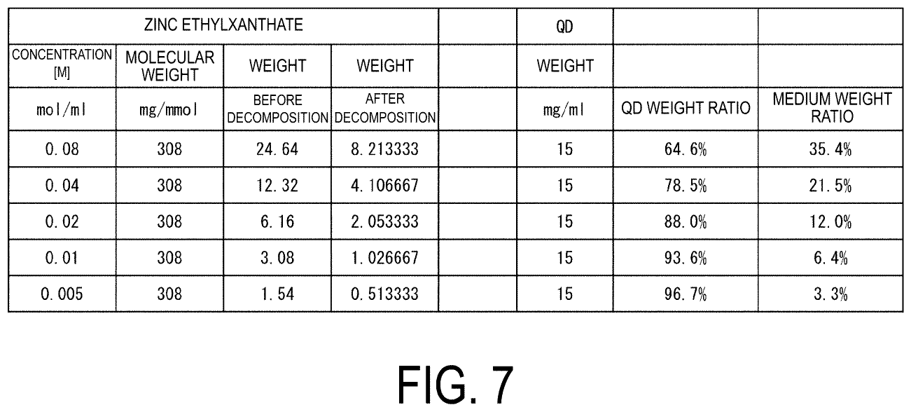

FIG. 7 is a table showing an example of a plurality of types of quantum dot solutions containing a plurality of quantum dots QD, a precursor of a metal sulfide, and a solvent, which can be used in a process of forming the red light-emitting layer 24REM of the red light-emitting element 5R provided in the display device 1 of the present embodiment.

As shown in FIG. 7, in the present embodiment, a case in which zinc ethylxanthate that forms ZnS by being decomposed after heat treatment is used as a precursor of a metal sulfide will be described as an example, but the disclosure is not limited thereto. As the precursor of the metal sulfide, a metal complex in which at least one selected from thiourea, N-methylthiourea, 1,3-dimethylthiourea, N,N′-dimethylthiourea, tetramethylthiourea, thioacetamide, and xanthic acid is coordinated to a metal atom may be used. In addition, the precursor of the metal sulfide may include a metal source and a sulfur source, the metal source may be at least one or more selected from a metal acetate, a metal nitrate, or a metal halide salt, and the sulfur source may be at least one or more selected from thiourea, N-methylthiourea, 1,3-dimethylthiourea, N,N′-dimethylthiourea, tetramethylthiourea, and thioacetamide.

In the present embodiment, a case in which the quantum dot QD including the core made of InP, the shell made of ZnS, and the halogen ligand as the ligand is used will be described as an example, but the disclosure is not limited thereto.

In the present embodiment, a case in which N,N-dimethylformamide is used as a solvent will be described as an example, but the disclosure is not limited thereto, and for example, dimethyl sulfoxide or the like may be used.

The quantum dot solution having a concentration [M] of 0.08 shown in FIG. 7 is a solution obtained by mixing the quantum dots QD, zinc ethylxanthate, and N,N-dimethylformamide such that the concentration of the quantum dots QD is 15 mg/ml and the concentration of zinc ethylxanthate, which is a precursor of the metal sulfide, is 24.64 mg/ml. A weight ratio of the quantum dots QD in the red light-emitting layer 24REM formed using the quantum dot solution having the concentration [M] of 0.08 is 64.6%, and a weight ratio of the continuous film MR (media) is 35.4%.

The quantum dot solution having a concentration [M] of 0.04 shown in FIG. 7 is a solution obtained by mixing the quantum dots QD, zinc ethylxanthate, and N,N-dimethylformamide such that the concentration of the quantum dots QD is 15 mg/ml and the concentration of zinc ethylxanthate, which is a precursor of the metal sulfide, is 12.32 mg/ml. A weight ratio of the quantum dots QD in the red light-emitting layer 24REM formed using the quantum dot solution having the concentration [M] of 0.04 is 78.5%, and the weight ratio of the continuous film MR (media) is 21.5%.

The quantum dot solution having a concentration [M] of 0.02 shown in FIG. 7 is a solution obtained by mixing the quantum dots QD, zinc ethylxanthate, and N,N-dimethylformamide such that the concentration of the quantum dots QD is 15 mg/ml and the concentration of zinc ethylxanthate, which is a precursor of the metal sulfide, is 6.16 mg/ml. A weight ratio of the quantum dots QD in the red light-emitting layer 24REM formed using the quantum dot solution having the concentration [M] of 0.02 is 88.0%, and the weight ratio of the continuous film MR (media) is 12.0%.

The quantum dot solution having a concentration [M] of 0.01 shown in FIG. 7 is a solution obtained by mixing the quantum dots QD, zinc ethylxanthate, and N,N-dimethylformamide such that the concentration of the quantum dots QD is 15 mg/ml and the concentration of zinc ethylxanthate, which is a precursor of the metal sulfide, is 3.08 mg/ml. A weight ratio of the quantum dots QD in the red light-emitting layer 24REM formed using the quantum dot solution having the concentration [M] of 0.01 is 93.6%, and the weight ratio of the continuous film MR (media) is 6.4%.

The quantum dot solution having a concentration [M] of 0.005 shown in FIG. 7 is a solution obtained by mixing the quantum dots QD, zinc ethylxanthate, and N,N-dimethylformamide such that the concentration of the quantum dots QD is 15 mg/ml and the concentration of zinc ethylxanthate, which is a precursor of the metal sulfide, is 1.54 mg/ml. A weight ratio of the quantum dots QD in the red light-emitting layer 24REM formed using the quantum dot solution having the concentration [M] of 0.005 is 96.7%, and the weight ratio of the continuous film MR (media) is 3.3%.

Even in the red light-emitting layer 24REM formed using any of the quantum dot solutions having the concentrations [M] of 0.08, 0.04, 0.02, 0.01, and 0.005 shown in FIG. 7, in a cross section of a portion of the red light-emitting layer 24REM including cross sections of 50 or more quantum dots QD among the plurality of quantum dots QD included in the red light-emitting layer 24REM, the area A of the cross section of the continuous film MR including the metal sulfide is smaller than the area B obtained by adding the areas of the cross sections of the 50 or more quantum dots QD.

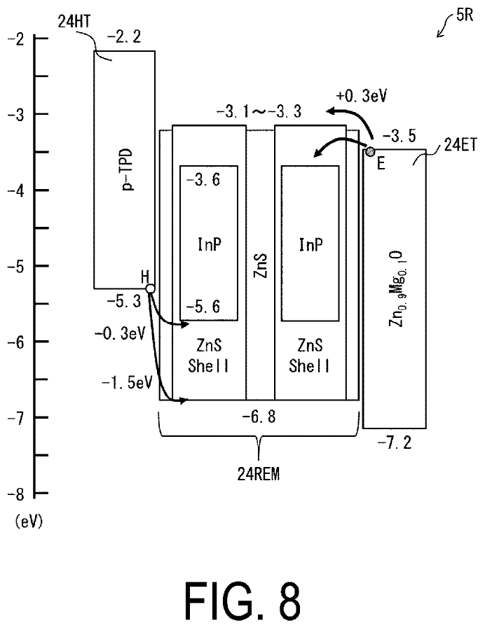

FIG. 8 is a diagram schematically illustrating band levels of the hole transport layer 24HT, the red light-emitting layer 24REM, and the electron transport layer 24ET, which are included in the red light-emitting element 5R of the display device 1 of the present embodiment.

In a cross section of a portion of the red light-emitting layer 24REM including cross sections of 50 or more quantum dots QD among the plurality of quantum dots QD included in the red light-emitting layer 24REM included in the red light-emitting element 5R, the area A of the cross section of the continuous film MR including the metal sulfide is smaller than the area B obtained by adding the areas of the cross sections of the 50 or more quantum dots QD.

According to such a configuration, as illustrated in FIG. 8, holes H are injected from a valence band maximum level (−5.3 eV) of the hole transport layer 24HT into a valence band maximum level (−5.6 eV) of the core CO of the quantum dots QD and a valence band maximum level (−6.8 eV) of the shell SH of the quantum dots QD, and electrons E are injected from a conduction band minimum level (−3.5 eV) of the electron transport layer 24ET into a conduction band minimum level (−3.6 eV) of the core CO of the quantum dots QD and a conduction band minimum level (−3.1 eV to −3.3 eV) of the shell SH of the quantum dots QD, so that a good balance of carriers of the holes H and the electrons E can be ensured.

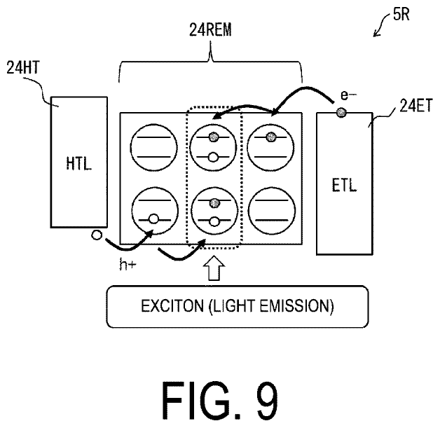

FIG. 9 is a diagram for explaining the reason why a good external quantum efficiency (EQE) can be achieved in the red light-emitting element 5R of the display device 1 of the present embodiment.

In the case of the red light-emitting element 5R, as described above, since a good balance of carriers of the holes H and the electrons E can be ensured, as illustrated in FIG. 9, the holes H and the electrons E are recombined at the center of the red light-emitting layer 24REM and emit light as excitons, and thus, the good external quantum efficiency (EQE) can be achieved. The red light-emitting element 5R can improve the durability and the luminous efficiency.

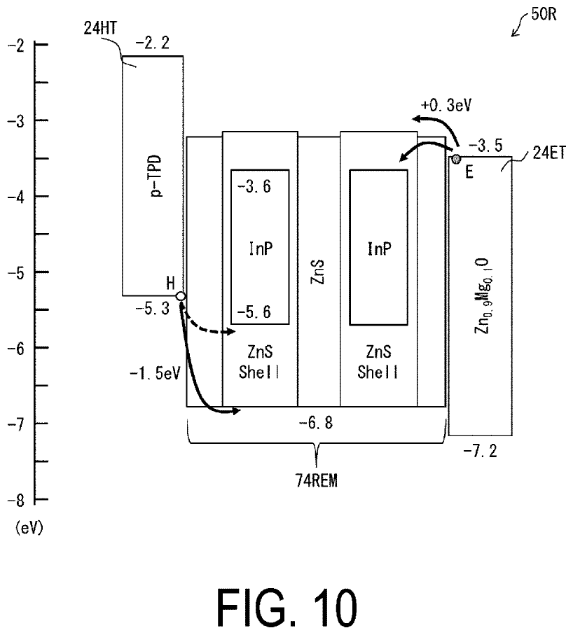

FIG. 10 is a diagram schematically illustrating band levels of the hole transport layer 24HT, a red light-emitting layer 74REM, and the electron transport layer 24ET, which are included in a red light-emitting element 50R of a comparative example.

The red light-emitting layer 74REM included in the red light-emitting element 50R of the comparative example is, for example, a layer formed using a quantum dot solution having a concentration [M] of 0.3. The quantum dot solution having the concentration [M] of 0.3 is a solution obtained by mixing the quantum dots QD, zinc ethylxanthate, and N,N-dimethylformamide so that the concentration of the quantum dots QD is 15 mg/ml and the concentration of zinc ethylxanthate, which is a precursor of the metal sulfide, is 92.4 mg/ml. A weight ratio of the quantum dots QD in the red light-emitting layer 74REM formed using the quantum dot solution having the concentration [M] of 0.3 is 32.7%, and the weight ratio of the continuous film MR (media) is 67.3%. Note that the concentration of zinc ethylxanthate serving as the precursor of the metal sulfide is 30.8 mg/ml after the heat treatment due to decomposition.

In a cross section of a portion of the red light-emitting layer 74REM including cross sections of 50 or more quantum dots QD among the plurality of quantum dots QD included in the red light-emitting layer 74REM, the area A of the cross section of the continuous film MR including the metal sulfide is larger than the area B obtained by adding areas of the cross sections of the 50 or more quantum dots QD.

In a cross section of a portion of the red light-emitting layer 74REM including cross sections of 50 or more quantum dots QD among the plurality of quantum dots QD included in the red light-emitting layer 74REM included in the red light-emitting element 50R of the comparative example, the area A of the cross section of the continuous film MR containing the metal sulfide is larger than the area B obtained by adding the areas of the cross sections of the 50 or more quantum dots QD.

According to such a configuration, as illustrated in FIG. 10, the holes H are mainly injected from the valence band maximum level (−5.3 eV) of the hole transport layer 24HT into the valence band maximum level (−6.8 eV) of the shell SH of the quantum dots QD having a relatively large level difference of 1.5 eV, and are hardly injected to the valence band maximum level (−5.6 eV) of the core CO of the quantum dots QD having a relatively small level difference of 0.3 eV, due to the influence of the continuous film MR containing the metal sulfide occupying a large portion in the red light-emitting layer 74REM. On the other hand, since the electrons E are injected from the conduction band minimum level (−3.5 eV) of the electron transport layer 24ET to the conduction band minimum level (−3.6 eV) of the core CO of the quantum dots QD and the conduction band minimum level (−3.1 eV to −3.3 eV) of the shell SH of the quantum dots QD, the red light-emitting layer 74REM is in a state in which the electrons E are excessive, and the carriers of the holes H and the electrons E are unbalanced.

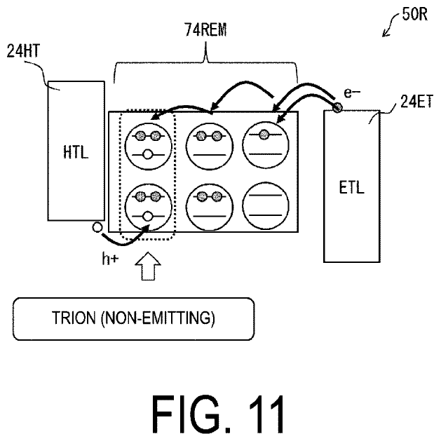

FIG. 11 is a diagram for explaining the reason why a good external quantum efficiency (EQE) cannot be achieved in the red light-emitting element 50R of the comparative example.

As illustrated in FIG. 11, in the red light-emitting layer 74REM in a state in which the electrons E are excessive, two electrons E and one hole H form a trione state, and the layer does not emit light through the trione state and is thermally deactivated, so that a good external quantum efficiency (EQE) cannot be achieved.

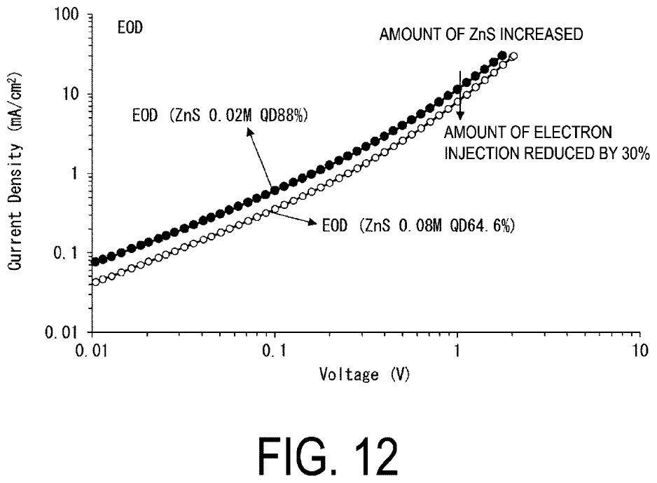

FIG. 12 is a graph illustrating the relationship between voltage and current density of an electron only device (EOD) including the red light-emitting layer 24REM formed using a quantum dot solution having a concentration of 0.02 M and an electron only device (EOD) including the red light-emitting layer 24REM formed using a quantum dot solution having a concentration of 0.08 M among the plurality of types of quantum dot solutions shown in FIG. 7.

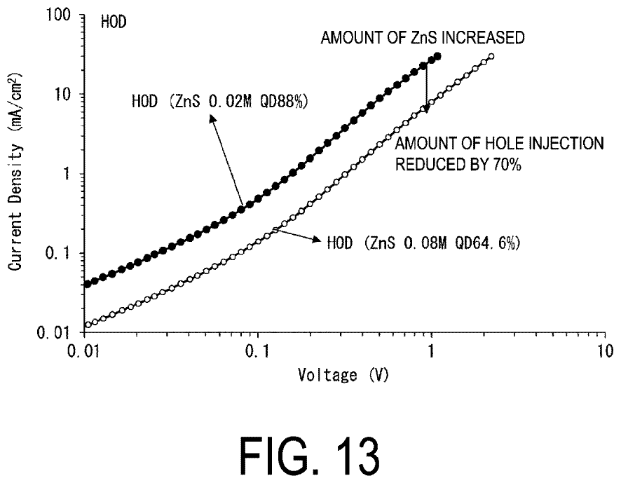

FIG. 13 is a graph illustrating the relationship between voltage and current density of a hole only device (HOD) including the red light-emitting layer 24REM formed using a quantum dot solution having a concentration of 0.02 M and a hole only device (HOD) including the red light-emitting layer 24REM formed using a quantum dot solution having a concentration of 0.08 M among the plurality of types of quantum dot solutions shown in FIG. 7.

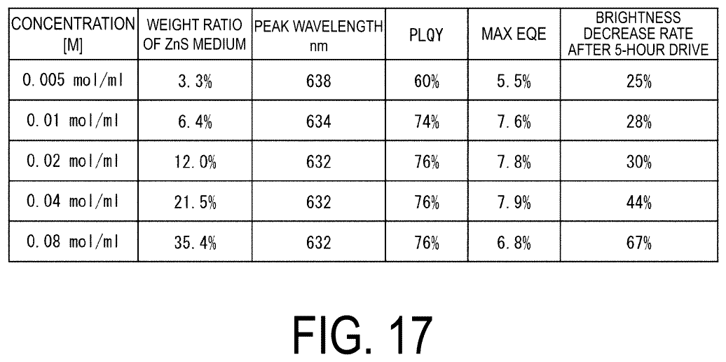

FIG. 17 is a table showing light-emission peak wavelengths, internal quantum yields (PLQY), maximum external quantum efficiencies (maximum EQE), and brightness decrease rates after a 5-hour drive of a plurality of types of red light-emitting elements 5R including the red light-emitting layers 24REM formed using the plurality of types of quantum dot solutions shown in FIG. 7.

As illustrated in FIG. 12, when a voltage applied to the electron only device (EOD) is set to a certain constant value, and an injection amount of the electrons E in the electron only device (EOD) including the red light-emitting layer 24REM formed using the quantum dot solution having a concentration of 0.02 M is compared with the injection amount of the electrons E in the electron only device (EOD) including the red light-emitting layer 24REM formed using the quantum dot solution having a concentration of 0.08 M, it can be confirmed that the injection amount of the electrons E is reduced by 30% when the concentration is increased by four times.

On the other hand, as illustrated in FIG. 13, when the voltage applied to the hole only device (HOD) is set to a certain constant value, and an injection amount of the holes H in the hole only device (HOD) including the red light-emitting layer 24REM formed using the quantum dot solution having a concentration of 0.02 M is compared with the injection amount of the holes H in the hole only device (HOD) including the red light-emitting layer 24REM formed using the quantum dot solution having a concentration of 0.08 M, it can be confirmed that the injection amount of the holes H is reduced by 70% when the concentration is increased by four times.

As described above, it can be confirmed that the decrease in the injection amount of the holes H is significantly larger than the decrease in the injection amount of the electrons E with the increase in the concentration. This can be understood from the band levels illustrated in FIGS. 8 and 10.

From the viewpoint of ensuring a better balance of carriers of holes H and electrons E and achieving a better external quantum efficiency (EQE), it is preferable to form the red light-emitting layer 24REM using a quantum dot solution having the concentration [M] of any one of 0.08, 0.04, 0.02, and 0.01, which exhibits a relatively high maximum EQE of 6.8% or more, as shown in FIG. 17.

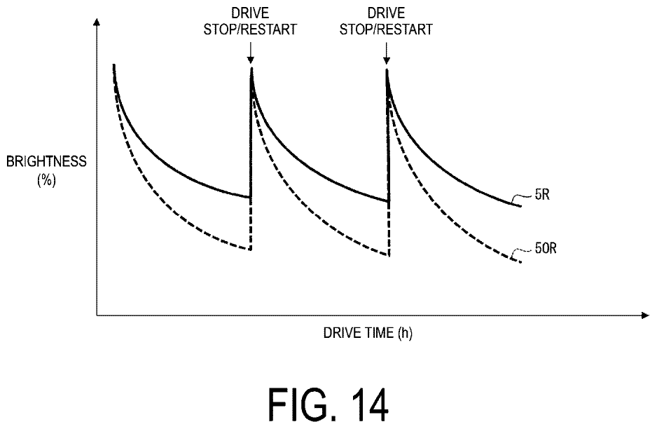

FIG. 14 is a graph illustrating a degree of brightness decrease due to charge-up of the quantum dots QD when the red light-emitting element 5R including the red light-emitting layer 24REM formed using the quantum dot solution having a concentration of 0.01 M among the plurality of types of quantum dot solutions shown in FIG. 7 and the red light-emitting element 50R of the comparative example illustrated in FIG. 10 are intermittently driven.

As illustrated in FIG. 14, when the red light-emitting element 5R and the red light-emitting element 50R of the comparative example are intermittently driven by repeating a drive period, which is a continuous energization period of a certain period, and a non-drive period, which is a non-energization period of a certain period, a temporary brightness decrease occurs more significantly in the red light-emitting element 50R of the comparative example than in the red light-emitting element 5R during the drive period, which is the continuous energization period of a certain period. The temporary brightness decrease occurring in the drive period which is the continuous energization period of a certain period is caused by charge-up of the quantum dots QD, and is a reversible brightness decrease which can be eliminated by applying a reverse voltage or leaving the quantum dots QD without energization.

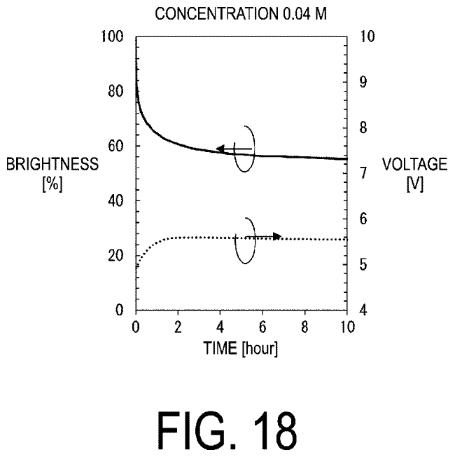

FIG. 18 is a graph illustrating a change in brightness and a change in voltage according to a drive time of the red light-emitting element 5R including the red light-emitting layer 24REM formed using a quantum dot solution having a concentration of 0.04 M among the plurality of types of quantum dot solutions shown in FIG. 7.

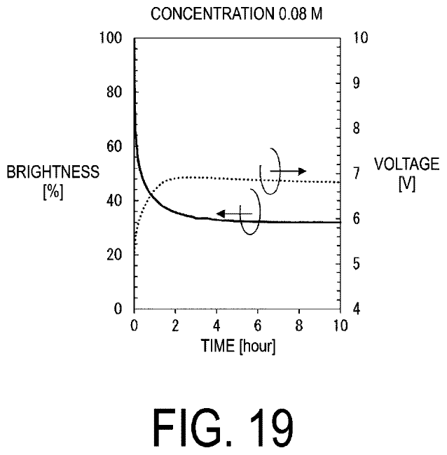

FIG. 19 is a graph illustrating a change in brightness and a change in voltage according to a drive time of the red light-emitting element 5R including the red light-emitting layer 24REM formed using a quantum dot solution having a concentration of 0.08 M among the plurality of types of quantum dot solutions shown in FIG. 7.

An initial brightness decrease rate (for example, the brightness decrease rate for up to one hour) of the red light-emitting element 5R including the red light-emitting layer 24REM formed using the quantum dot solution having the concentration of 0.04 M illustrated in FIG. 18 is significantly suppressed compared to the initial brightness decrease rate (for example, the brightness decrease rate for up to one hour) of the red light-emitting element 5R including the red light-emitting layer 24REM formed using the quantum dot solution having the concentration of 0.08 M illustrated in FIG. 19.

In addition, the increase in the initial drive voltage (for example, the increase in the drive voltage for up to one hour) of the red light-emitting element 5R including the red light-emitting layer 24REM formed using the quantum dot solution having the concentration of 0.04 M illustrated in FIG. 18 is significantly suppressed compared to the increase in the initial drive voltage (for example, the increase in the drive voltage for up to one hour) of the red light-emitting element 5R including the red light-emitting layer 24REM formed using the quantum dot solution having the concentration of 0.08 M illustrated in FIG. 19.

From the above, in consideration of the initial brightness decrease rate (for example, the brightness decrease rate for up to one hour), the increase in the initial drive voltage (for example, the increase in the initial drive voltage for up to one hour), and the brightness decrease rate after a 5-hour drive shown in FIG. 17, it is preferable to form the red light-emitting layer 24REM using the quantum dot solution having the concentration [M] of any one of 0.04, 0.02, 0.01, and 0.005 among the plurality of types of quantum dot solutions shown in FIG. 7.

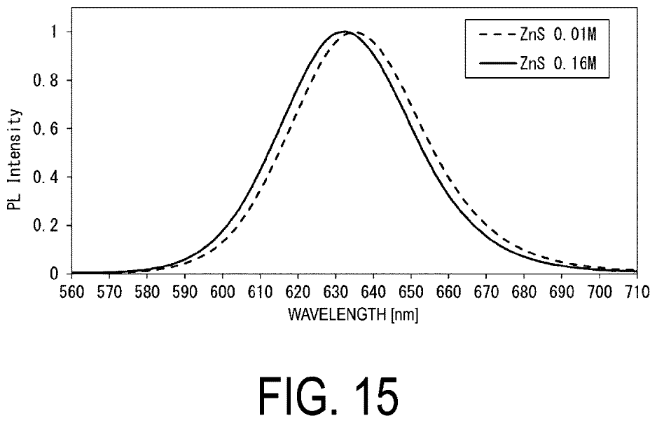

FIG. 15 is a graph illustrating photoluminescence (PL) intensities at wavelengths of the red light-emitting layer 24REM formed using a quantum dot solution having a concentration of 0.01 M among the plurality of types of quantum dot solutions shown in FIG. 7 and a red light-emitting layer formed using a quantum dot solution having a concentration of 0.16 M of a comparative example.

As illustrated in FIG. 15, a light-emission peak wavelength of the red light-emitting layer formed using the quantum dot solution having the concentration of 0.16 M of the comparative example is 632 nm, and the light-emission peak wavelength of the red light-emitting layer 24REM formed using the quantum dot solution having the concentration of 0.01 M is 634 nm, and the light-emission peak wavelength is shifted to a long-wavelength side due to the decrease in concentration, but the shift amount is as good as 2 nm.

Such a shift of the light-emission peak wavelength to the long-wavelength side is considered to be due to an increase in Förster resonance energy transfer (FRET). As shown in FIG. 17, the light-emission peak wavelengths of the red light-emitting layers 24REM formed using the quantum dot solutions having the concentrations of 0.02 M, 0.04 M, and 0.08 M are all 632 nm, and no shift of the light-emission peak wavelengths to the long-wavelength side is observed. This is considered to be because in the case of the red light-emitting layer 24REM formed using each of the quantum dot solutions having the concentrations of 0.02 M, 0.04 M, and 0.08 M, the distance between the cores of the quantum dots QD can be secured to be a certain level or more, and Förster resonance energy transfer (FRET) can be suppressed. On the other hand, in the case of the red light-emitting layer 24REM formed using the quantum dot solution having the concentration of 0.005 M, it is considered that the distance between the cores of the quantum dots QD cannot be secured to a certain level or more, and the light-emission peak wavelength is shifted to the long-wavelength side due to an increase in Förster resonance energy transfer (FRET).

From the above, in consideration of the shift amount of the light-emission peak wavelength to the long-wavelength side, it is preferable to form the red light-emitting layer 24REM using the quantum dot solution having the concentration [M] of any one of 0.08, 0.04, 0.02, and 0.01 among the plurality of types of quantum dot solutions shown in FIG. 7.

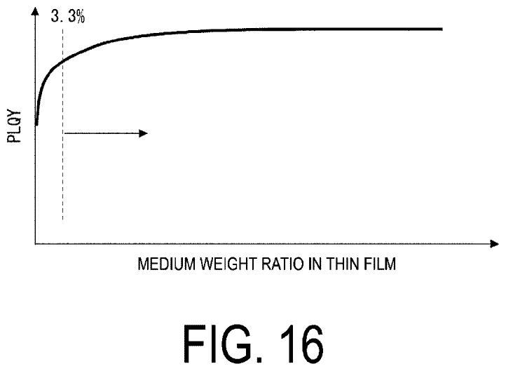

FIG. 16 is a graph illustrating the relationship between the weight ratio of the continuous film MR as media containing a metal sulfide in a plurality of types of red light-emitting layers 24REM, which are thin films formed using a plurality of types of quantum dot solutions shown in FIG. 7, and the internal quantum yield (photoluminescence quantum yield (PLQY)).

As shown in FIGS. 16 and 17, in the case of the red light-emitting element 5R including the red light-emitting layer 24REM formed using the quantum dot solution having the concentration [M] of 0.005 among the plurality of types of quantum dot solutions shown in FIG. 7, a weight ratio of the ZnS medium in the red light-emitting layer 24REM is 3.3%, and the internal quantum yield (PLQY) is 60%, which is a good value. In addition, in each of the red light-emitting elements 5R including the red light-emitting layers 24REM formed using the quantum dot solutions having the concentrations [M] of 0.01, 0.02, 0.04, and 0.08, the weight ratios of the ZnS medium in the red light-emitting layers 24REM are 6.4% to 35.4%, and the internal quantum yields (PLQY) are 74% to 76%, which are good values.

From the above, in consideration of the internal quantum yield (PLQY), it is preferable to form the red light-emitting layer 24REM using the quantum dot solution having the concentration [M] of any one of 0.08, 0.04, 0.02, 0.01, and 0.005 among the plurality of types of quantum dot solutions shown in FIG. 7.

As shown in FIG. 17, in consideration of all the suppression of the shift of the light-emission peak wavelength, the internal quantum yield (PLQY), the maximum external quantum efficiency (maximum EQE), and the brightness decrease rate after a 5-hour drive, the weight ratio of the ZnS medium in the red light-emitting layer 24REM is preferably greater than 3.3% and less than 35%, and for example, the red light-emitting layer 24REM is preferably formed using the quantum dot solution having the concentration [M] of any one of 0.04, 0.02, and 0.01 among the plurality of types of quantum dot solutions shown in FIG. 7. In the case of the red light-emitting element 5R including the red light-emitting layer 24REM formed using the quantum dot solution having the concentration [M] of any one of 0.04, 0.02, and 0.01, the shift amount of the light-emission peak wavelength can be suppressed to 0 to 2 nm, the internal quantum yield (PLQY) can be achieved at 74% to 76%, the maximum external quantum efficiency (maximum EQE) can be achieved at 7.6% to 7.9%, and the brightness decrease rate after a 5-hour drive can be suppressed to 28% to 44%.

When the weight ratio of the ZnS medium in the red light-emitting layer 24REM is greater than 3.3% and less than 35%, in a cross section of a portion of the red light-emitting layer 24REM including cross sections of a predetermined number, for example, 50 or more quantum dots QD among the plurality of quantum dots QD included in the red light-emitting layer 24REM, the area A of the cross section of the continuous film MR containing the metal sulfide as the matrix is 3.4% or more and 27.0% or less of the area B obtained by adding the areas of the cross sections of the predetermined number, for example, the 50 or more quantum dots QD.

When the weight ratio of the ZnS medium in the red light-emitting layer 24REM is greater than 3.3% and less than 35%, the volume of the continuous film MR containing the metal sulfide as the matrix in the red light-emitting layer 24REM is 3.6% or more and 37.1% or less of the volume of the red light-emitting layer 24REM.

Note that a value of the preferable volume of the continuous film MR containing the metal sulfide with respect to the volume of the red light-emitting layer 24REM described above can be calculated, for example, as follows. For example, when InP having a density of 4.81 g/cm³ is used as the core material of the quantum dots QD, ZnS having a density of 4.09 g/cm³ is used as the shell material of the quantum dots QD, a diameter of the core of the quantum dots QD is 3.2 nm, and a thickness of the shell of the quantum dots QD is 0.5 nm, the average density of the quantum dots QD can be 4.41g/cm³. When the ZnS medium is mixed with 15 mg of the quantum dots QD at 0.005 M, which is the lower limit, the weight of the ZnS medium is 3.3% and the volume of the ZnS medium is 3.6%. On the other hand, when the ZnS medium is mixed with 15 mg of the quantum dots QD at 0.08 M, which is the upper limit, the weight of the ZnS medium is 35.4% and the volume of the ZnS medium is 37.1%.

In addition, a preferable area A of the cross section of the continuous film MR containing the metal sulfide with respect to the area B obtained by adding the areas of the cross sections of the predetermined number of quantum dots QD described above, for example, 50 or more quantum dots QD can be calculated, for example, as follows. When the volume of the quantum dot QD is V (QD) and the volume of the ZnS medium is V (MR), the volume V (24REM) of the red light-emitting layer 24REM is V (QD)+V (MR). When a thickness of a sample (a thickness in a depth direction in FIG. 4) in observation with a transmission electron microscopy (TEM) is defined as a radius r of the quantum dot QD, a cross-sectional area of the quantum dot QD is ((V (QD)+V (MR))/r). Further, when the radius of the quantum dot QD is r, the volume V (QD) of each of n quantum dots QD is 4/3×π×r³, and the maximum cross-sectional area of the quantum dot QD is πr², but the sum of the cross-sectional areas of the n quantum dots QD cut at random positions is 0.66 nπr². Therefore, a cross-sectional area of the ZnS medium when the volume of the ZnS medium is 3.6% of the red light-emitting layer 24REM is 3.4% of the red light-emitting layer 24REM, and the cross-sectional area of the ZnS medium when the volume of the ZnS medium is 37.1% of the red light-emitting layer 24REM is 27.0% of the entire of the red light-emitting layer 24REM.

In addition, a transmission electron microscopy (TEM) image of a cross section of a portion of the red light-emitting layer 24REM including cross sections of 50 or more quantum dots QD among the plurality of quantum dots QD may include a first region corresponding to an area of a cross section of the continuous film MR containing the metal sulfide and having a higher electron density in transmission by an irradiated electron beam, and a second region corresponding to an area obtained by adding areas of the cross sections of the 50 or more quantum dots QD and having a lower electron density, the red light-emitting layer 24REM may have a width L orthogonal to the cross section of the red light-emitting layer 24REM, a value F obtained by adding a product D of the area of the first region and the width L and a product E of the area of the second region and the width L may be a volume of the portion of the red light-emitting layer 24REM, and the product D may be a volume of the continuous film MR containing the metal sulfide as a matrix in the portion of the red light-emitting layer 24REM.

Further, the red light-emitting layer 24REM may include a first region having a unique diffraction peak of the metal sulfide by X-ray diffraction and a second region having a unique diffraction peak of the quantum dots QD by X-ray diffraction, the area of the first region in the cross section of the red light-emitting layer 24REM obtained based on the unique diffraction peak of the metal sulfide by X-ray diffraction may be an area G, the area of the second region in the cross section of the red light-emitting layer 24REM obtained based on the unique diffraction peak of the quantum dots by X-ray diffraction may be an area H, the red light-emitting layer 24REM may have the width L orthogonal to the cross section of the red light-emitting layer 24REM, a value K obtained by adding a product I of the area G and the width L and a product J of the area H and the width L may be a volume of a portion of the red light-emitting layer 24REM, and the product I may be a volume of the continuous film MR containing the metal sulfide as a matrix in the portion of the red light-emitting layer 24REM.

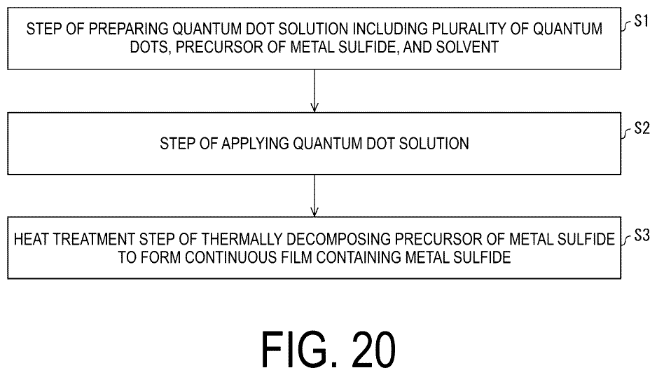

FIG. 20 is a flow chart for explaining a process of forming the red light-emitting layer 24REM included in a method for manufacturing the red light-emitting element 5R provided in the display device 1 of the present embodiment.

As illustrated in FIG. 20, the process of forming the red light-emitting layer 24REM included in the method for manufacturing the red light-emitting element 5R provided in the display device 1 includes a step (S1) of preparing a quantum dot solution containing a plurality of quantum dots QD, a precursor of the metal sulfide, and a solvent, a step (S2) of applying the quantum dot solution, and a heat treatment step (S3) of thermally decomposing the precursor of the metal sulfide to form a continuous film MR containing the metal sulfide as a matrix.

In the step (S1) of preparing the quantum dot solution illustrated in FIG. 20, the amount of the plurality of quantum dots and the amount of the precursor of the metal sulfide contained in the quantum dot solution are adjusted such that a value of ((weight of red light-emitting layer 24REM−weight of quantum dots QD)/weight of red light-emitting layer 24REM)×100% in the red light-emitting layer 24REM after the heat treatment step (S3) is greater than 3.3% and less than 35%.

Although not shown, the method for manufacturing the red light-emitting element 5R includes a process of forming one of the anode 22 and the cathode 25, a process of forming the red light-emitting layer 24REM described above, and a process of forming the other of the anode 22 and the cathode 25.

Note that in the present embodiment, the red light-emitting element 5R is taken as an example to describe the configuration and the manufacturing method thereof, but the configuration and the manufacturing method thereof can be similarly applied to the green light-emitting element 5G and the blue light-emitting element 5B.

### Appendix

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

### INDUSTRIAL APPLICABILITY

The disclosure may be utilized in a light-emitting element, a display device, and a method for manufacturing a light-emitting element, and method for forming a light-emitting layer.

1. A light-emitting element comprising:
an anode;
a cathode; and
a light-emitting layer provided between the anode and the cathode,
wherein the light-emitting layer includes a matrix including a metal sulfide and a plurality of quantum dots enclosed in the matrix, and
in a cross section of a portion of the light-emitting layer including cross sections of a predetermined number of quantum dots among the plurality of quantum dots, an area C of the cross section of the portion of the light-emitting layer is smaller than twice an area B obtained by adding areas of the cross sections of the predetermined number of quantum dots.

2. The light-emitting element according to claim 1,
wherein an area A obtained by subtracting the area B from the area C is 3.4% or more and 27.0% or less of the area B.

3. The light-emitting element according to claim 1,
wherein a transmission electron microscopy (TEM) image of the cross section of the light-emitting layer includes a first region in which an electron density is relatively high in transmission by an irradiated electron beam and a second region in which the electron density is relatively low,
an area of the first region is an area A obtained by subtracting the area B from the area C, and
an area of the second region is the area B.

4. The light-emitting element according to claim 1,
wherein the cross section of the light-emitting layer includes a first region having a unique diffraction peak of the metal sulfide by X-ray diffraction and a second region having a unique diffraction peak of the plurality of quantum dots by X-ray diffraction,
an area of the first region in the cross section of the light-emitting layer obtained based on a unique diffraction peak of the metal sulfide by X-ray diffraction is an area A obtained by subtracting the area B from the area C, and
an area of the second region in the cross section of the light-emitting layer obtained based on a unique diffraction peak of the plurality of quantum dots by X-ray diffraction is the area B.

5. A light-emitting element comprising:
an anode;
a cathode; and
a light-emitting layer provided between the anode and the cathode,
wherein the light-emitting layer includes a matrix including a metal sulfide and a plurality of quantum dots enclosed in the matrix, and
a volume of the matrix in the light-emitting layer is 3.6% or more and 37.1% or less of a volume of the light-emitting layer.

6. The light-emitting element according to claim 5,
wherein a transmission electron microscopy (TEM) image of a cross section of a portion of the light-emitting layer including cross sections of a predetermined number of quantum dots among the plurality of quantum dots includes a first region corresponding to an area of a cross section of the matrix, in which an electron density is relatively high in transmission by an irradiated electron beam, and a second region corresponding to an area obtained by adding areas of the cross sections of the predetermined number of quantum dots, in which the electron density is relatively low,
the light-emitting layer has a width L orthogonal to the cross section of the light-emitting layer,
a value F obtained by adding a product D of an area of the first region and the width L and a product E of an area of the second region and the width L is a volume of a portion of the light-emitting layer, and
the product D is a volume of the matrix in the portion of the light-emitting layer.

7. The light-emitting element according to claim 5,
wherein the light-emitting layer includes a first region having a unique diffraction peak of the metal sulfide by X-ray diffraction and a second region having a unique diffraction peak of the plurality of quantum dots by X-ray diffraction,
an area of the first region in a certain surface of the light-emitting layer obtained based on a unique diffraction peak of the metal sulfide by X-ray diffraction is an area G,
an area of the second region in the certain surface of the light-emitting layer obtained based on a unique diffraction peak of the plurality of quantum dots by X-ray diffraction is an area H,
the light-emitting layer has a width L orthogonal to the certain surface of the light-emitting layer,
a value K obtained by adding a product I of the area G and the width L and a product J of the area H and the width L is a volume of the light-emitting layer, and
the product I is a volume of the matrix in the light-emitting layer.

8. The light-emitting element according to claim 1,
wherein in a cross section of a portion of the light-emitting layer including cross sections of a predetermined number of quantum dots among the plurality of quantum dots, a number-average inter-quantum dot distance of the predetermined number of quantum dots is 1 nm or more and 5 nm or less.

9. The light-emitting element according to claim 1,
wherein each of the plurality of quantum dots includes a core and a shell,
the shell of each of the plurality of quantum dots is made of a metal sulfide, and
a band gap of the matrix is larger than a band gap of the core of each of the plurality of quantum dots.

10. The light-emitting element according to claim 1,
wherein each of the plurality of quantum dots includes a core and a shell,
the shell of each of the plurality of quantum dots is made of a material other than a metal sulfide, and
a band gap of the matrix is larger than a band gap of the core of each of the plurality of quantum dots.

11. The light-emitting element according to claim 1,
wherein the metal sulfide includes one or more metal elements selected from Zn, Mg, and Ga.

12. The light-emitting element according to claim 11,
wherein the metal sulfide is any of zinc sulfide, magnesium zinc sulfide, gallium sulfide, zinc sulfide selenide, zinc sulfide telluride, magnesium sulfide, and gallium zinc sulfide.

13. The light-emitting element according to claim 12,
wherein the metal sulfide is zinc sulfide.

14. A display device comprising:
the light-emitting element according to claim 1.

15. (canceled)

16. A method for forming a light-emitting layer comprising:
preparing a quantum dot solution including a plurality of quantum dots, a precursor of a metal sulfide, and a solvent;
applying the quantum dot solution; and
performing a heat treatment of thermally decomposing the precursor of the metal sulfide to form a matrix including the metal sulfide,
wherein in the preparing the quantum dot solution, an amount of the plurality of quantum dots and an amount of the precursor of the metal sulfide included in the quantum dot solution are adjusted such that a value of ((weight of light-emitting layer−weight of quantum dots)/weight of light-emitting layer)×100% in the light-emitting layer after the performing the heat treatment is greater than 3.3% and less than 35%.

17. A method for manufacturing a light-emitting element, comprising:
forming one of an anode and a cathode;
forming a light-emitting layer by the method for forming a light-emitting layer according to claim 16; and
forming the other of the anode and the cathode.
